(19) United States
(12) Patent Application Publication
(10) Pub. No.: US 2026/0026319 A1
(43) Pub. Date: Jan. 22, 2026

(54) WAFER PROCESSING METHOD

(71) Applicant: UNITED MICROELECTRONICS CORP., Hsin-Chu City (TW)

(72) Inventors: Ang Chan, Taipei City (TW); Hsin-Jung Liu, Pingtung County (TW); Chau-Chung Hou, Kaohsiung City (TW); Jhih-Yuan Chen, Kaohsiung City (TW); Wei-Xin Gao, Tainan City (TW); Hsiang-Chi Chien, Pingtung County (TW)

(73) Assignee: UNITED MICROELECTRONICS CORP., Hsin-Chu City (TW)

(21) Appl. No.: 18/792,589

(22) Filed: Aug. 2, 2024

(30) Foreign Application Priority Data
Jul. 18, 2024 (TW) 113126925

(51) Int. Cl. H01L 21/02; H01L 21/18

(52) U.S. Cl. CPC H01L 21/02013; H01L 21/02016; H01L 21/02021; H01L 21/02118; H01L 21/185

(57) ABSTRACT

A wafer processing method is disclosed. A second wafer is bonded to a first wafer. The rear surface of the second wafer is subjected to a first grinding process, thereby thinning the second wafer to a first thickness. A sacrificial layer is formed on the rear surface of the second wafer. A one-step wafer edge trimming process is then performed to remove an outer edge region of the sacrificial layer and the second wafer in one-step cut using a blade. The sacrificial layer is removed from the rear surface of the second wafer.

### BACKGROUND OF THE INVENTION

### 1. Field of the Invention

The present invention relates to the field of semiconductor technology, and in particular, to an improved wafer processing method.

### 2. Description of the Prior Art

Wafer edge trimming is a critical step in the manufacturing of hybridized wafers, which involve bonding multiple silicon wafers together to create complex semiconductor devices. Edge trimming eliminates imperfections and inconsistencies along the wafer edges, providing a smooth and consistent surface for bonding. This ensures a strong and uniform adhesive bond between the wafers, minimizing the risk of delamination or cracking during subsequent processing steps.

During wafer edge trimming, mechanical stresses are induced at the wafer edge due to the cutting forces. These stresses can cause microcracks to form and propagate, leading to chipping. To reduce chipping, some parameters used during the wafer edge trimming such as feed rate and depth of cut are carefully controlled.

Feed rate, also known as cutting speed, may significantly impact the occurrence of chipping. It refers to the rate at which the diamond blade advances along the edge of the wafer during the trimming process. As the feed rate increases, the cutting forces exerted on the wafer edge also increase. These higher forces can lead to the formation and propagation of microcracks, resulting in chipping.

Current wafer edge trimming employs multi-stage cutting process that uses different combinations of feed rates and processing time periods. The multi-stage cutting process involves fragmenting the edge removal into multiple steps, employing a series of progressively finer cutting tools. Each stage removes a small portion of the edge material, distributing the stress throughout the cutting zone rather than concentrating it at a single point.

However, each additional stage adds to the overall trimming time. While the benefit is smoother edges and less chipping, it comes at the cost of reduced production throughput, especially for high-volume manufacturing.

### SUMMARY OF THE INVENTION

It is one object of the present invention to provide an improved wafer processing method to solve the deficiencies or shortcomings of the existing technology.

One aspect of the invention provides a wafer processing method including the steps of bonding a second wafer to a first wafer; subjecting a rear surface of the second wafer to a first grinding process, thereby thinning the second wafer to a first thickness; forming a sacrificial layer on the rear surface of the second wafer; performing an one-step wafer edge trimming process to remove an outer edge region of the sacrificial layer and the second wafer in one-step cut using a blade; and removing the sacrificial layer from the rear surface of the second wafer.

According to some embodiments, the one-step wafer edge trimming process is performed at a constant feed rate.

According to some embodiments, the constant feed rate is greater than 5 degrees per second.

According to some embodiments, the blade is a diamond blade having an average particle size that is equal to or greater than 30 micrometer.

According to some embodiments, the sacrificial layer comprises a silicon oxide layer, a silicon nitride layer, a silicon carbide layer, a silicon oxynitride layer, or any combinations thereof.

According to some embodiments, the sacrificial layer comprises a polyurethane film, a polyimide film or a polyester film.

According to some embodiments, a process time period of the one-step wafer edge trimming process is less than 72 seconds.

According to some embodiments, the first thickness is 230-680 micrometers.

According to some embodiments, after removing the sacrificial layer from the rear surface of the second wafer, the rear surface of the second wafer is subjected to a second grinding process, thereby thinning the second wafer to a second thickness.

According to some embodiments, the second thickness is 8-100 micrometers.

According to some embodiments, the second wafer comprises a device layer adjacent to a front surface that is directly bonded to the first wafer.

According to some embodiments, an outer portion of the first wafer is also removed during the one-step wafer edge trimming process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 are schematic diagrams of a wafer processing method according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

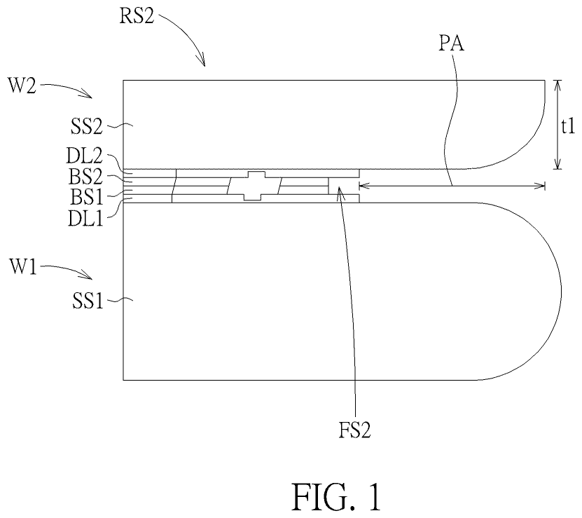

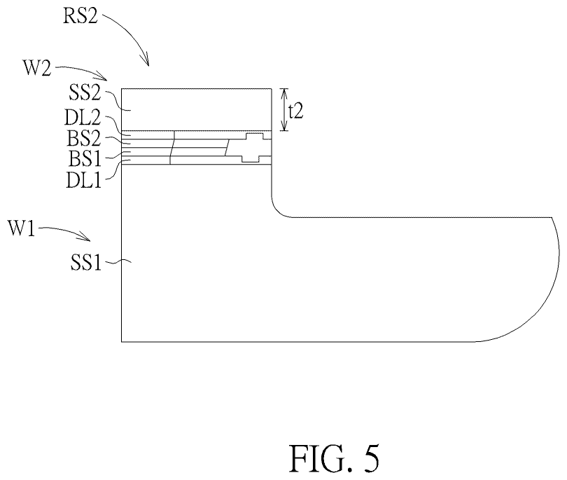

Please refer to FIG. 1 to FIG. 5, which are schematic diagrams of a wafer processing method according to an embodiment of the present invention. As shown in FIG. 1, a first wafer W1 and a second wafer W2 are provided, and a hybrid bonding process is performed to bond the second wafer W2 to the first wafer W1. According to an embodiment of the present invention, the first wafer W1 includes, for example, a semiconductor substrate SS1, a device layer DL1 and a bonding layer BS1. According to an embodiment of the present invention, the second wafer W2 includes, for example, a semiconductor substrate SS2, a device layer DL2, and a bonding layer BS2. According to an embodiment of the present invention, for example, the bonding layer BS1 and the bonding layer BS2 may include metal patterns and dielectric layers, but are not limited thereto. According to an embodiment of the present invention, the device layer DL2 of the second wafer W2 is adjacent to the front surface FS2 of the second wafer W2.

When performing the above hybrid bonding process, the metal patterns of the bonding layer BS1 and the bonding layer BS2 are aligned with each other and directly bonded together. In addition, the annular outer edge region PA along the periphery of the bonded wafer may be an un-bonded area and subsequently needs to be trimmed and removed to a selected depth.

According to an embodiment of the present invention, a first grinding process, such as a chemical mechanical polishing (CMP) process, is then performed on the rear surface RS2 of the second wafer W2, thereby thinning the second wafer W2 to a first thickness t1. According to an embodiment of the present invention, for example, the first thickness t1 may range from 230-680 micrometers, but is not limited thereto.

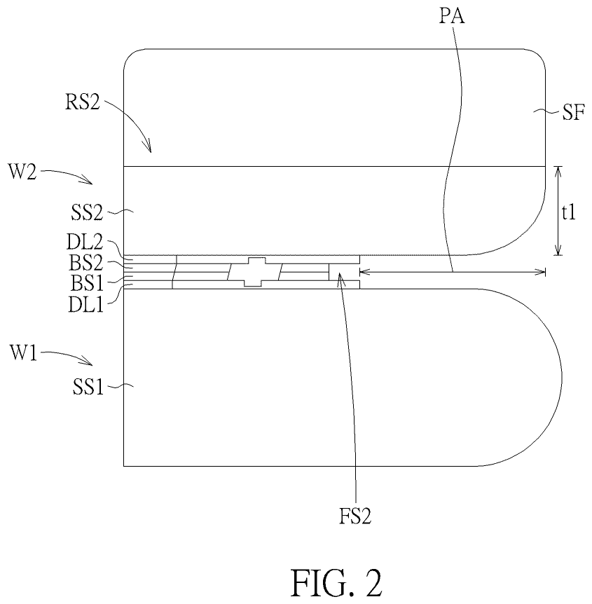

As shown in FIG. 2, next, a sacrificial layer SF is formed on the rear surface RS2 of the second wafer W2. According to an embodiment of the present invention, the sacrificial layer SF may be deposited using a chemical vapor deposition (CVD) method or a film attach method. According to an embodiment of the present invention, for example, the sacrificial layer SF may include a silicon oxide layer, a silicon nitride layer, a silicon carbide layer, a silicon oxynitride layer, or any combinations thereof. According to some embodiments of the present invention, for example, the sacrificial layer SF may include a polyurethane film, a polyimide film, or a polyester film.

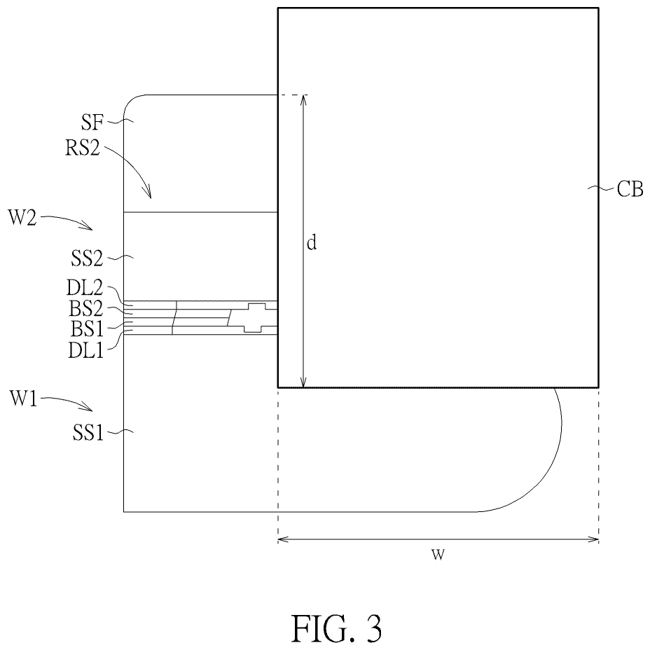

As shown in FIG. 3, a one-step wafer edge trimming process is then performed, and the blade CB is used to cut and remove the sacrificial layer SF and the outer edge region PA of the second wafer W2 in one step to the selected depth d, where the selected depth d is, for example, 300 micrometers, and the width w of the blade CB is, for example, about 2.8 mm, which can cover the annular outer edge region PA. According to an embodiment of the present invention, while performing the one-step wafer edge trimming process, the outer portion of the first wafer W1 is also removed.

According to an embodiment of the present invention, for example, the blade CB may be a diamond blade with an average particle size equal to or greater than 30 micrometers. According to an embodiment of the present invention, the one-step wafer edge trimming process is performed with the same blade CB and at a constant feed rate throughout the entire process, without intermittent tool changes in the middle, and the wafer edge trimming is completed in one step. According to an embodiment of the present invention, for example, the fixed feed rate may be greater than 5 degrees per second to increase throughput. According to an embodiment of the present invention, the process time period of the one-step wafer edge trimming process may be less than 72 seconds.

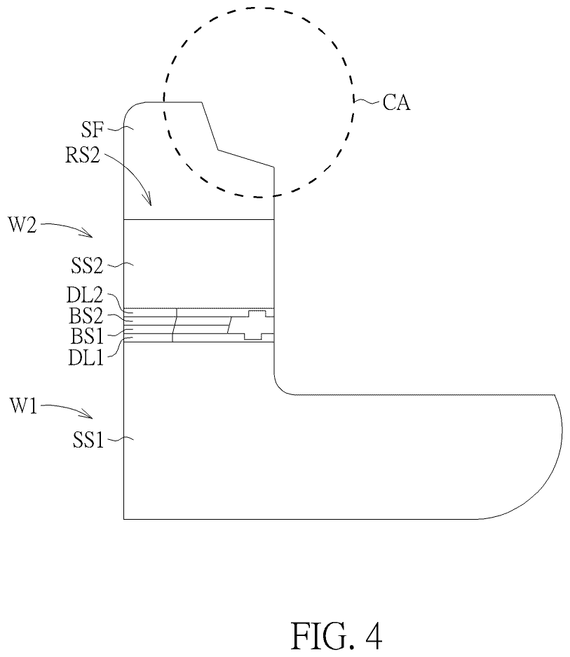

As shown in FIG. 4, after completing the one-step wafer edge trimming process, the blade CB is removed. At this point, although cracks may occur around the sacrificial layer SF, as shown in the dotted area CA, it will not occur on the second wafer W2 and damage to the second wafer W2 can be avoided.

As shown in FIG. 4, next, the sacrificial layer SF is removed from the rear surface RS2 of the second wafer W2. According to an embodiment of the present invention, after removing the sacrificial layer SF on the rear surface RS2 of the second wafer W2, a second grinding process, such as a chemical mechanical polishing (CMP) process, can be performed on the rear surface RS2 of the second wafer W2, and the second wafer W2 is thinned to a second thickness t2. According to an embodiment of the present invention, for example, the second thickness t2 may range from 8-100 micrometers, but is not limited thereto.

One technical feature of the present invention is to form a sacrificial layer SF on the rear surface RS2 of the second wafer W2 after performing the first grinding process on the rear surface RS2 of the second wafer W2. In this way, a one-step wafer edge trimming process can be performed, and the entire process is carried out with the same blade and at a constant feed rate throughout the entire process, without intermittent tool changes in the middle, and the wafer edge trimming is completed in one step, which significantly improves the productivity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A wafer processing method, comprising:
bonding a second wafer to a first wafer;
subjecting a rear surface of the second wafer to a first grinding process, thereby thinning the second wafer to a first thickness;
forming a sacrificial layer on the rear surface of the second wafer;
performing an one-step wafer edge trimming process to remove an outer edge region of the sacrificial layer and the second wafer in one-step cut using a blade; and
removing the sacrificial layer from the rear surface of the second wafer.

2. The wafer processing method according to claim 1, wherein the one-step wafer edge trimming process is performed at a constant feed rate.

3. The wafer processing method according to claim 2, wherein the constant feed rate is greater than 5 degrees per second.

4. The wafer processing method according to claim 1, wherein the blade is a diamond blade having an average particle size that is equal to or greater than 30 micrometer.

5. The wafer processing method according to claim 1, wherein the sacrificial layer comprises a silicon oxide layer, a silicon nitride layer, a silicon carbide layer, a silicon oxynitride layer, or any combinations thereof.

6. The wafer processing method according to claim 1, wherein the sacrificial layer comprises a polyurethane film, a polyimide film or a polyester film.

7. The wafer processing method according to claim 1, wherein a process time period of the one-step wafer edge trimming process is less than 72 seconds.

8. The wafer processing method according to claim 1, wherein the first thickness is 230-680 micrometers.

9. The wafer processing method according to claim 1 further comprising:
after removing the sacrificial layer from the rear surface of the second wafer, subjecting the rear surface of the second wafer to a second grinding process, thereby thinning the second wafer to a second thickness.

10. The wafer processing method according to claim 9, wherein the second thickness is 8-100 micrometers.

11. The wafer processing method according to claim 1, wherein the second wafer comprises a device layer adjacent to a front surface that is directly bonded to the first wafer.

12. The wafer processing method according to claim 1, wherein an outer portion of the first wafer is also removed during the one-step wafer edge trimming process.
